(19) United States
(12) Patent Application Publication
(10) Pub. No.: US 2024/0258249 A1
(43) Pub. Date: Aug. 1, 2024

(54) SEMICONDUCTOR PACKAGE MEMBER AND SEMICONDUCTOR DEVICE

(71) Applicant: ROHM Co., LTD., Kyoto (JP)

(72) Inventor: Shunsuke Akasaka, Kyoto (JP)

(21) Appl. No.: 18/415,810

(22) Filed: Jan. 18, 2024

(30) Foreign Application Priority Data
Jan. 26, 2023 (JP) 2023-010159

(51) Int. Cl. H01L 23/00; H01L 23/053; H01L 23/08

(52) U.S. Cl. CPC H01L 23/564; H01L 23/053; H01L 23/08

(57) ABSTRACT

Provided is a semiconductor package member including a substrate having a first main surface on which a recess is formed, in which the substrate includes a plurality of through holes formed in such a manner as to, from a first main surface, reach a second main surface opposite to the first main surface, and at least some of the plurality of through holes are formed at positions overlapping the recess.

### CROSS REFERENCE TO RELATED APPLICATIONS

This application claims priority benefit of Japanese Patent Application No. JP 2023-010159 filed in the Japan Patent Office on Jan. 26, 2023. Each of the above-referenced applications is hereby incorporated herein by reference in its entirety.

### BACKGROUND

The present disclosure relates to a semiconductor package member and a semiconductor device.

Japanese Patent Laid-open No. 2012-78089 (Patent Document 1) discloses a gas sensor that includes a gas sensing section and a cover that has gas permeability. The gas-permeable cover includes a metal lid. A plurality of holes are provided in the metal lid.

### BRIEF DESCRIPTION OF THE DRAWINGS

FIG. 1 is a schematic cross-sectional view of a semiconductor device according to a first embodiment;

FIG. 2 is a schematic plan view of the semiconductor device according to the first embodiment;

FIG. 3 is a partially enlarged plan view of region III in FIG. 2;

FIG. 4 is a partially enlarged sectional view taken along line IV-IV in FIG. 3;

FIG. 5 is a partially enlarged sectional view illustrating a modification of the semiconductor device according to the first embodiment;

FIG. 6 is a partially enlarged plan view illustrating a modification of the semiconductor device according to the first embodiment;

FIG. 7 is a flowchart of a method for manufacturing the semiconductor device according to the first embodiment;

FIG. 8 is a schematic cross-sectional view illustrating one step in a method for manufacturing a semiconductor package member according to the first embodiment;

FIG. 9 is a schematic cross-sectional view illustrating a step subsequent to the step illustrated in FIG. 8 in the method for manufacturing a semiconductor package member according to the first embodiment;

FIG. 10 is a schematic cross-sectional view illustrating a step subsequent to the step illustrated in FIG. 9 in the method for manufacturing a semiconductor package member according to the first embodiment;

FIG. 11 is a schematic cross-sectional view illustrating a step subsequent to the step illustrated in FIG. 10 in the method for manufacturing a semiconductor package member according to the first embodiment;

FIG. 12 is a schematic cross-sectional view illustrating a step subsequent to the step illustrated in FIG. 11 in the method for manufacturing a semiconductor package member according to the first embodiment;

FIG. 13 is a schematic cross-sectional view illustrating a step subsequent to the step illustrated in FIG. 12 in the method for manufacturing a semiconductor package member according to the first embodiment;

FIG. 14 is a schematic cross-sectional view illustrating a semiconductor device according to a second embodiment; and

FIG. 15 is a schematic cross-sectional view illustrating a semiconductor device according to a third embodiment.

### DETAILED DESCRIPTION

Details of embodiments of the present disclosure will be described in reference to the drawings. In the following drawings, the same or equivalent parts are given the same reference numbers, and the description thereof will not be repeated. At least some of the configurations of the embodiments described below may freely be combined.

### First Embodiment

### <Structure of Semiconductor Device>

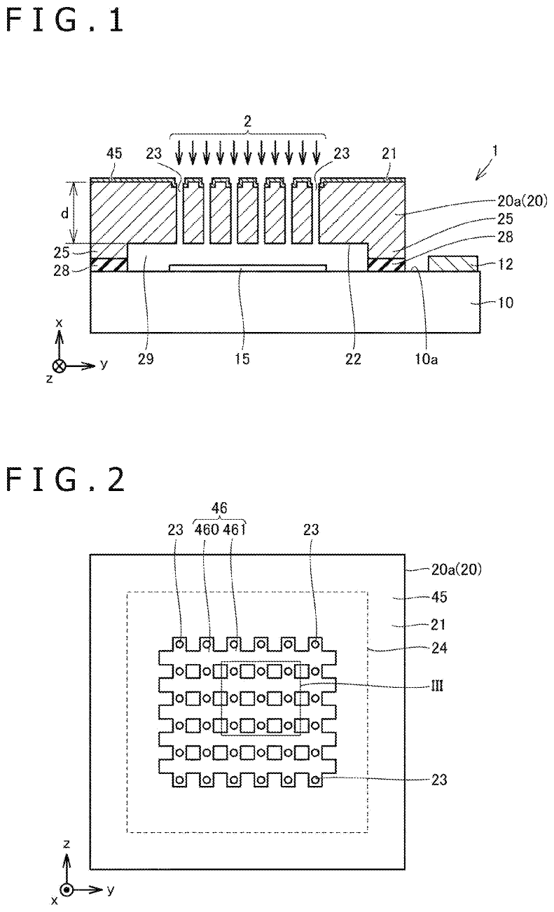

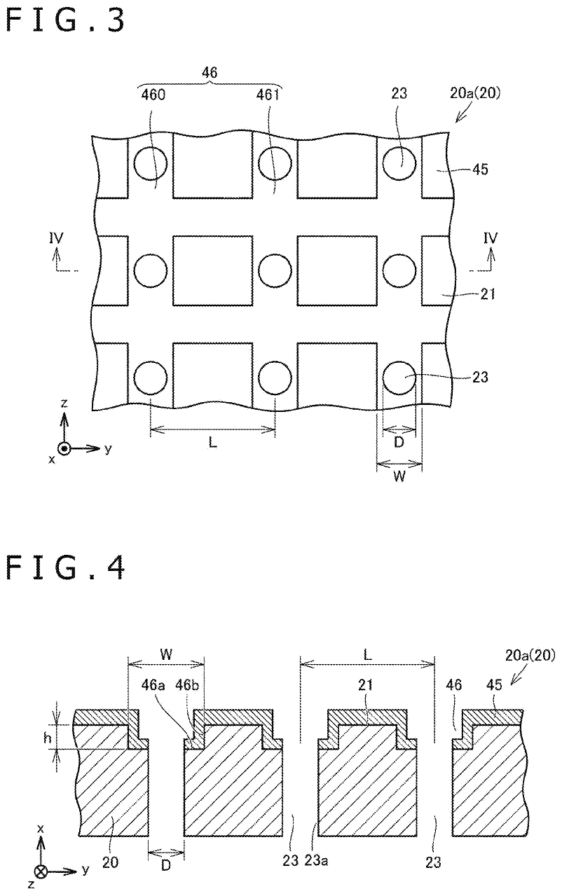

FIG. 1 is a schematic cross-sectional view of a semiconductor device according to a first embodiment. FIG. 2 is a schematic plan view of the semiconductor device according to the first embodiment. FIG. 3 is a partially enlarged plan view of region III in FIG. 2. FIG. 4 is a partially enlarged sectional view taken along line IV-IV in FIG. 3.

A semiconductor device 1 illustrated in FIGS. 1 to 4 is a gas sensor that detects gas, and mainly includes a support substrate 10, a semiconductor element 15, and a semiconductor package member 20, for example.

The support substrate 10 supports the semiconductor element 15. The support substrate 10 is a printed circuit board, for example. The support substrate 10 includes electrical wiring (not illustrated) and external terminals 12. The support substrate 10 has a first surface 10a. The external terminals 12 are provided on the first surface 10a, for example. The external terminals 12 are arranged on the outside of the semiconductor package member 20 in plan view in a direction perpendicular to the first surface 10a. The external terminals 12 are connected to the electrical wiring of the support substrate 10. The external terminals 12 are connected to the semiconductor element 15 through the electrical wiring of the support substrate 10.

The semiconductor element 15 detects gas 2 in the environment surrounding the semiconductor device 1. Specifically, the semiconductor element 15 detects the gas 2 that has flowed into a cavity 29 of the semiconductor device 1 through a plurality of through holes 23 of the semiconductor package member 20, and outputs a signal regarding the gas 2 such as the concentration of the gas 2. The signal regarding the gas 2 is output to the outside of the semiconductor device 1 through the electrical wiring of the support substrate 10 and the external terminals 12. The gas 2 detected by the semiconductor element 15 is not particularly limited to any kind, and includes methane, hydrogen, oxygen, carbon monoxide, or nitrogen oxide (NOₓ), for example. The semiconductor element 15 is a semiconductor gas sensor chip, for example, although it is not particularly limited to any kind.

The semiconductor package member 20 covers the semiconductor element 15. The semiconductor package member 20 includes a semiconductor material such as silicon (Si). The semiconductor package member 20 includes a substrate 20a. The substrate 20a has a first main surface 21 and a second main surface 22. The second main surface 22 faces the semiconductor element 15. The first main surface 21 is a surface opposite to the second main surface 22. A distance d from the first main surface 21 to the second main surface 22 in a first direction X is greater than 0.1 mm, for example. Thus, the mechanical strength of the semiconductor package member 20 is improved. The distance d from the first main surface 21 to the second main surface 22 in the first direction X may be 0.5 mm or more, or 1.0 mm or more, for example.

Note that, in the present specification, a direction perpendicular to the first main surface 21 is defined as the first direction X, as illustrated in FIG. 1. As illustrated in FIG. 2, directions perpendicular to the first direction X are defined as a second direction Y and a third direction Z. The third direction Z is a direction perpendicular to the second direction Y. That is, the second direction Y and the third direction Z are directions parallel to the first main surface 21.

The substrate 20a includes the plurality of through holes 23. The plurality of through holes 23 allow the surrounding environment of the semiconductor device 1 to communicate with the cavity 29 of the semiconductor device 1. Each of the plurality of through holes 23 is formed in such a manner as to reach the second main surface 22 from the first main surface 21. As illustrated in FIG. 3, an inner peripheral width D (diameter) of each of the plurality of through holes 23 is 0.05 mm or less. Thus, the semiconductor package member 20 satisfies the protection grade IPX4 or higher in the waterproof property test (JIS C 0920). The inner peripheral width D of each of the plurality of through holes 23 may be 0.03 mm or less. The inner peripheral width D of each of the plurality of through holes 23 is 20 nm or more, for example. Thus, the gas moisture permeability of the semiconductor package member 20 can be prevented from becoming excessively low. The semiconductor package member 20 may have a protection grade of IPX8 or lower in the waterproof property test (JIS C 0920).

The area ratio of the plurality of through holes 23 is 10% or more, for example. Thus, the moisture permeability of the semiconductor package member 20 is enhanced, and the response speed of the semiconductor device 1 is improved. The area ratio of the plurality of through holes 23 may be 20% or more, or may be 30% or more. The area ratio of the plurality of through holes 23 is provided by dividing the area of the plurality of through holes 23 in plan view of the first main surface 21 by the area of a region 24 facing the cavity 29 of the semiconductor device 1 in the first main surface 21 in plan view of the first main surface 21. The moisture permeability of the semiconductor package member 20 is 100 g/(m²·h) or more, for example. The moisture permeability of the semiconductor package member 20 may be 150 g/(m²·h) or more, or may be 200 g/(m²·h) or more.

As illustrated in FIG. 2, the shape of the through hole 23 may be circular, for example, in plan view seen from the first direction X. When the shape of the through hole 23 is circular, the inner peripheral width D of the through hole 23 is the diameter. In the plan view seen from the first direction X, the shape of the through hole 23 may be a polygon such as a quadrangle or a pentagon, for example. In the plan view seen from the first direction X, the shape of the through hole 23 may 23 may be an ellipse, for example.

The semiconductor package member 20 is fixed to the support substrate 10 with use of a bonding member 28. Specifically, the substrate 20a includes a protrusion 25 protruding from the second main surface 22. The protrusion 25 is bonded to the first surface 10a of the support substrate 10 with use of the bonding member 28. Thus, even if the first surface 10a of the support substrate 10 is flat, the cavity 29 in which the semiconductor element 15 can be housed can be formed between the semiconductor package member 20 and the support substrate 10.

Here, the feature of the semiconductor device 1 according to the present first embodiment is that a recess 46 is formed on the first main surface 21 of the substrate 20a in the semiconductor package member 20, as illustrated in FIGS. 3 and 4. Specifically, as illustrated in FIG. 4, the recess 46 has a bottom surface 46a and a first side surface 46b. The bottom surface 46a is connected to the first side surface 46b. The first side surface 46b is connected to the first main surface 21. As illustrated in FIG. 4, the bottom surface 46a is arranged between the first main surface 21 and the second main surface 22 in the first direction X.

As illustrated in FIGS. 2 and 3, the plurality of through holes 23 are formed at positions overlapping the recess 46 in plan view when seen from the first direction X. Specifically, each of the plurality of through holes 23 may be formed in such a manner as to reach the second main surface 22 from the bottom surface 46a. In plan view when seen from the first direction X, at least some of the plurality of through holes 23 may be formed at positions overlapping the recess 46. Hence, all of the plurality of through holes 23 do not need to be formed in such a manner as to reach the second main surface 22 from the bottom surface 46a. That is, some of the plurality of through holes 23 may be formed in such a manner as to reach the second main surface 22 from the first main surface 21. Since the recess 46 is formed on the first main surface 21 in this manner, the first main surface 21 has water repellency. As a result, liquid such as water is repelled by surface tension on the first main surface 21, and the risk of water accumulating in the through hole 23 is greatly reduced.

As illustrated in FIGS. 3 and 4, a width W of the recess 46 in the second direction Y is preferably 0.1 mm or less. When the width W is 0.1 mm or more, there is a possibility that liquid such as water (water droplets) may enter the inside of the recess 46. The width W of the recess 46 in the second direction Y may be 0.08 mm or less. As the width W becomes smaller, the water repellency is further enhanced. On the other hand, the width W of the bottom surface 46a is preferably 0.05 mm or more so that the through hole 23 is formed in the bottom surface 46a. As illustrated in FIG. 4, a depth h of the recess 46 from the first main surface 21 to the bottom surface 46a in the first direction X may be equal to or greater than the width W.

As illustrated in FIG. 3, the recess 46 includes a first recess 460 and a second recess 461. On the first main surface 21, each of the first recess 460 and the second recess 461 may be formed to extend linearly.

On the first main surface 21, the second recess 461 may be formed to intersect with the first recess 460. Specifically, the first recess 460 may be formed to extend linearly in the third direction Z, and the second recess 461 may be formed to extend in the second direction Y.

In the first main surface 21, the first recess 460 and the second recess 461 may be formed parallel to each other, for example. Specifically, the first recess 460 and the second recess 461 may be formed to extend in the third direction Z.

As illustrated in FIG. 3, when the first recess 460 and the second recess 461 are formed to extend in the third direction Z, a distance L from the first recess 460 to the second recess 461 in the second direction Y may be three times or less the width W of the recess 46, for example. The distance L is the distance from the intermediate position of the first recess 460 in the second direction Y to the intermediate position of the second recess 461 in the second direction Y, as illustrated in FIG. 3. The distance L may be twice or less the width W, for example. In this way, the fine recesses 46 are arranged on the first main surface 21 in a congested manner, improving the water repellency of the semiconductor package member 20.

The first main surface 21 of the semiconductor package member 20 may be treated to be water repellent. Specifically, as illustrated in FIGS. 1 and 4, the semiconductor package member 20 may include a water-repellent film 45 formed on the first main surface 21 of the substrate 20a. The water-repellent film 45 contains a fluorine-based water repellent such as a fluorine resin or a silane containing a perfluoroalkyl group. Hence, the water repellency of the semiconductor device 1 can be further improved.

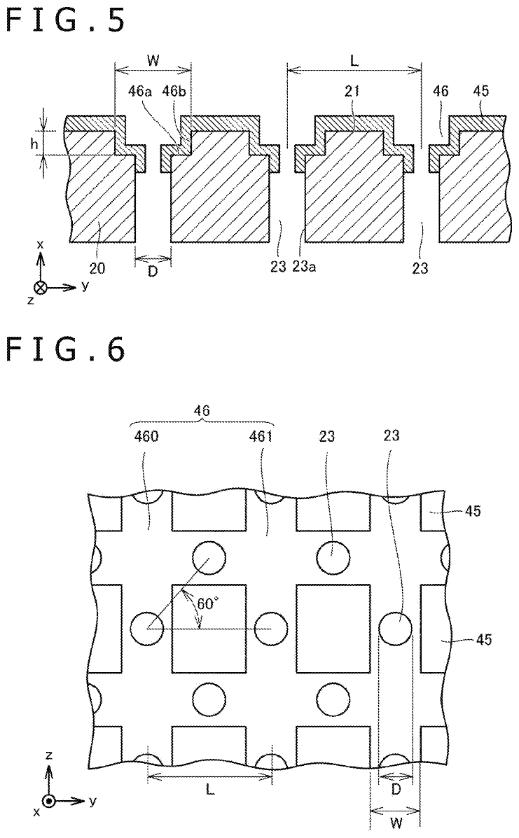

FIG. 5 illustrates a modification of the water-repellent film 45 of the semiconductor package member 20 illustrated in FIG. 4. FIG. 5 corresponds to FIG. 4. Inner peripheral surfaces of the through holes 23 and the recess 46 may be subjected to water repellent treatment. Specifically, the water-repellent film 45 may be in contact with at least a portion of a second side surface 23a of the through hole 23, the bottom surface 46a of the recess 46, and the first side surface 46b of the recess 46. The second side surface 23a is the inner peripheral surface of the through hole 23 connected to the bottom surface 46a and the second main surface 22. In this way, the water repellency of the semiconductor package member 20 is further improved.

The contact angle of water with respect to the first main surface 21 or the water-repellent film 45 is preferably 90° or more. When the contact angle with respect to liquid such as water is large, water repellency is high, making it difficult for water to accumulate in the through hole 23. Note that, by dropping liquid droplets on the first main surface 21 or the water-repellent film 45, the contact angle of water with respect to the first main surface 21 or the water-repellent film 45 can be measured. Specifically, 2 μL of pure water is dropped with use of a syringe onto the first main surface 21 or the water-repellent film 45, which is the contact surface. Thereafter, the image of state of the water droplet is captured from a side surface of the first main surface 21 or the water-repellent film 45. By the captured image being analyzed, the angle between the liquid surface and the contact surface (contact angle) can be measured.

As illustrated in FIG. 3, in plan view seen from the first direction X, the plurality of through holes 23 are arranged in a matrix. In plan view seen from the first direction X, the plurality of through holes 23 may be arranged at intervals in either the second direction Y or the third direction Z.

FIG. 6 illustrates a modification of the through holes 23 of the semiconductor package member 20 illustrated in FIG. 3. FIG. 6 corresponds to FIG. 3. The arrangement pattern of the plurality of through holes 23 may be staggered, for example. The plurality of through holes 23 may be arranged in a regular triangular lattice, for example. Specifically, the inner peripheral width D of each of the plurality of through holes 23 may be 0.03 mm. The distance between adjacent through holes 23 may be 0.06 mm. Among the adjacent through holes 23, the intersecting angle of the direction toward a through hole 23 shifted in the third direction Z when viewed from one through hole 23 with respect to the direction toward a through hole 23 shifted in the second direction Y when viewed from the one through hole 23 may be 60°. In this way, the plurality of through holes 23 may be arranged in any arrangement pattern.

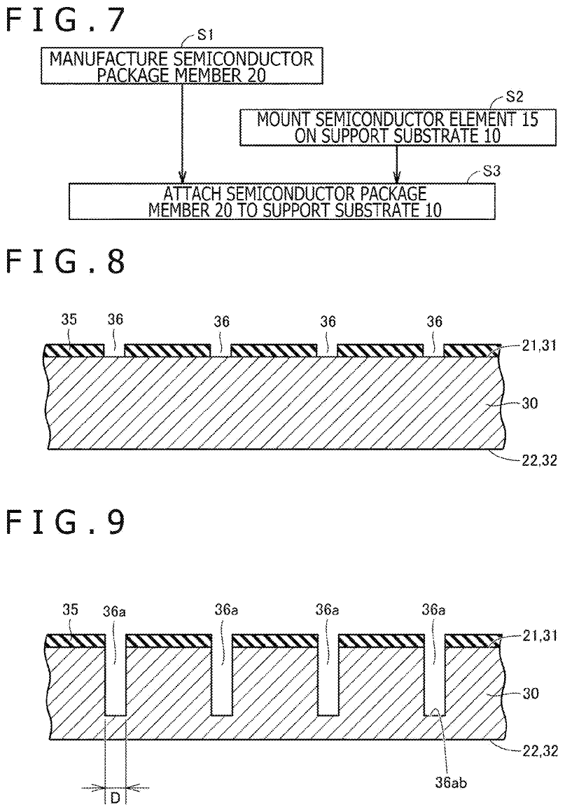

FIG. 7 is a flowchart illustrating a method for manufacturing the semiconductor device 1 according to the present first embodiment. The method for manufacturing the semiconductor device 1 will be described below.

A step (S1) of manufacturing the semiconductor package member 20 is performed. For example, the semiconductor package member 20 includes a semiconductor material and can be manufactured by a semiconductor process. The method for manufacturing the semiconductor package member 20 will be described in detail later.

A step (S2) of mounting the semiconductor element 15 on the support substrate 10 is performed. For example, the semiconductor element 15 is bonded to the support substrate 10 with use of a conductive bonding member (not illustrated) such as solder.

A step (S3) of attaching the semiconductor package member 20 to the support substrate 10 is performed. For example, the semiconductor package member 20 (specifically, the protrusion 25) is bonded to the first surface 10a of the support substrate 10 with use of the bonding member 28. The cavity 29 is formed between the semiconductor package member 20 and the support substrate 10. The semiconductor element 15 is housed within the cavity 29. The plurality of through holes 23 of the semiconductor package member 20 allow the surrounding environment of the semiconductor device 1 to communicate with the cavity 29.

A method for manufacturing the semiconductor package member 20 will be described below.

As illustrated in FIG. 8, a semiconductor substrate 30 is prepared. The semiconductor substrate 30 is an Si substrate, for example. The semiconductor substrate 30 includes a main surface 31 and a main surface 32 opposite to the main surface 31. The main surface 31 is the first main surface 21 of the semiconductor package member 20. The main surface 32 is the second main surface 22 of the semiconductor package member 20. The distance from the main surface 31 to the main surface 32 in the direction perpendicular to the main surface 31 may be greater than 0.3 mm, for example. A resist 35 is formed on the main surface 31. The resist 35 is subjected to patterning to form holes 36 in the resist 35. The inner peripheral width D of the hole 36 is 0.05 mm or less.

As illustrated in FIG. 9, the semiconductor substrate 30 is etched by the resist 35 being used as a mask, to form a plurality of recesses 36a on the semiconductor substrate 30. Each recess 36a is formed by deep reactive ion etching (DRIE). The recess 36a may be formed by DRIE in such a manner as to reach the main surface 32 from the main surface 31, for example, but as illustrated in FIG. 9, the recess 36a does not have to penetrate the semiconductor substrate 30 from the main surface 31 to the main surface 32. That is, the recess 36a may have a bottom surface 36ab. The bottom surface 36ab is positioned to be sandwiched between the main surface 31 and the main surface 32. The distance from the main surface 31 to the bottom surface 36ab in the direction perpendicular to the main surface 31 may be 0.25 mm or more but 0.3 mm or less, for example. In this way, the recess 36a having an inner peripheral width D of 0.05 mm or less is formed. Thereafter, the resist 35 is removed from the semiconductor substrate 30 by ashing.

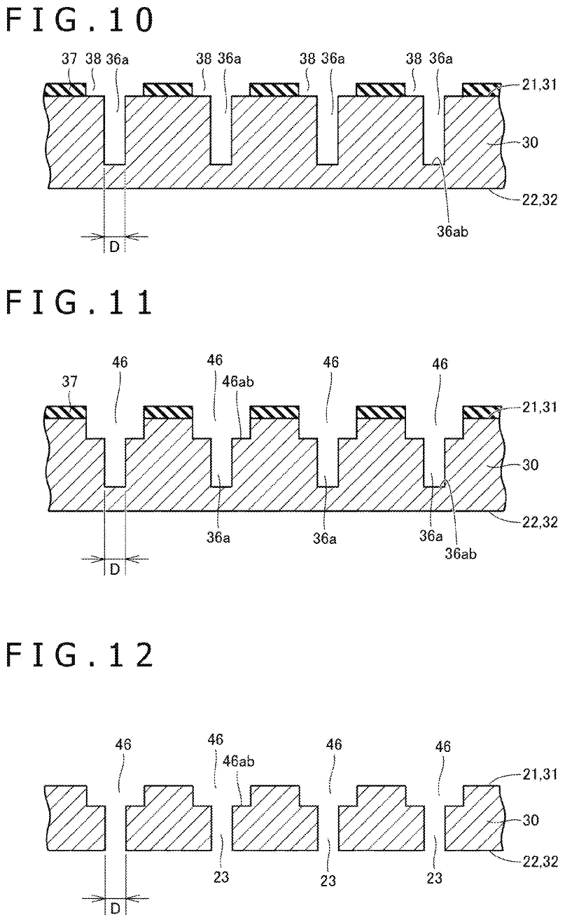

As illustrated in FIG. 10, a resist 37 is formed on the main surface 31. The resist 37 is subjected to patterning to form an opening 38 in the resist 37. When viewed from a direction perpendicular to the main surface 31, the openings 38 are preferably arranged in such a manner as to overlap the recesses 36a. In other words, it is sufficient if the resist 37 is patterned in such a manner as to avoid the region where the recess 36a is formed. Accordingly, the inner peripheral width of the opening 38 is 0.05 mm or more, for example.

As illustrated in FIG. 11, the semiconductor substrate 30 is etched by the resist 37 being used as a mask, to form the recess 46 in the semiconductor substrate 30. The recess 46 is formed by DRIE, for example. The recess 46 has a bottom surface 46ab. As illustrated in FIG. 11, the bottom surface 46abis positioned to be sandwiched between the main surface 31 and the bottom surface 36ab of the recess 36a. The distance from the main surface 31 to the bottom surface 46ab in the direction perpendicular to the main surface 31 is 0.06 mm, for example. Thereafter, the resist 37 is removed from the semiconductor substrate 30 by ashing.

As illustrated in FIG. 12, the main surface 32 of the semiconductor substrate 30 is ground and polished such that the thickness of the semiconductor substrate 30 becomes 0.25 mm. By grinding and polishing the main surface 32, the through hole 23 that reaches the surface opposite to the main surface 31 from the main surface 31 is formed. In this way, the plurality of through holes 23 each having an inner peripheral width D of 0.05 mm or less can easily be formed.

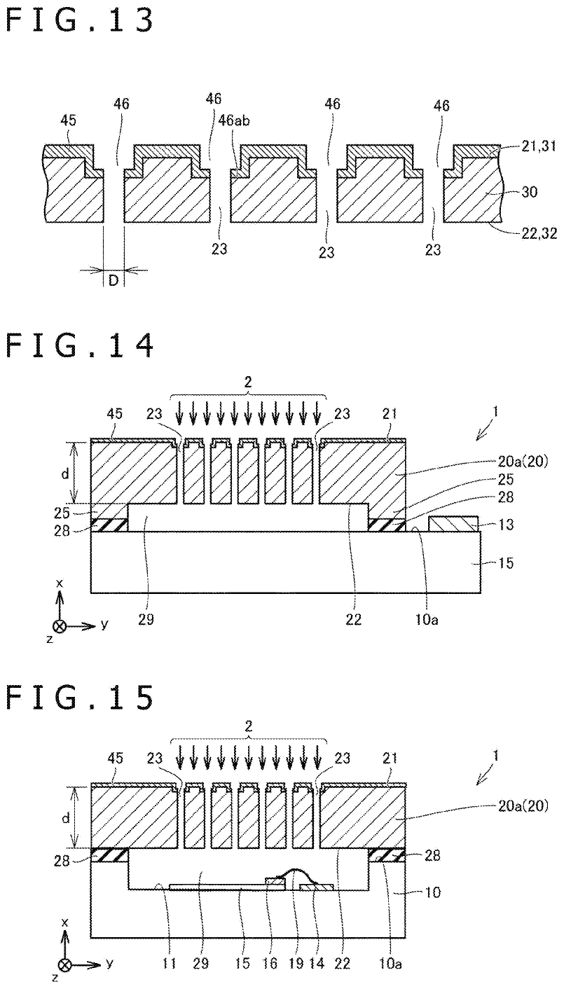

As illustrated in FIG. 13, the water-repellent film 45 is formed on the main surface 31 and the bottom surface 46ab. The contact angle of the main surface 31 is measured, and the water repellency of the semiconductor substrate 30 is checked. In this way, the semiconductor package member 20 having water repellency is obtained.

### <Operation>

The gas 2 in the environment surrounding the semiconductor device 1 flows into the cavity 29 of the semiconductor device 1 through the plurality of through holes 23 of the semiconductor package member 20. The semiconductor element 15 detects the gas 2 having flowed into the cavity 29 and outputs a signal regarding the gas 2 such as the concentration of the gas 2. A signal regarding the gas 2 is output to the outside of the semiconductor device 1 through the electrical wiring (not illustrated) and the external terminals 12 of the support substrate 10.

The inner peripheral width D of each of the plurality of through holes 23 is 0.05 mm or less. Thus, although the gas 2 can pass through the plurality of through holes 23, when liquid such as water flows into the through holes 23, the liquid accumulates in the plurality of through holes 23. As a result, the gas 2 may be unable to pass through the plurality of through holes 23, and the moisture permeability of the semiconductor device 1 decreases. Hence, the semiconductor package member 20 according to the present embodiment has water repellency, suppressing the inflow of liquid into the through hole 23. For example, the moisture permeability of the water-repellent semiconductor package member 20 is checked by a moisture permeability test (JIS Z 0208). Note that the moisture permeability test (JIS Z 0208) is performed by using the substrate 20a having an outer diameter of 70 mm or more.

The semiconductor package member 20 includes a semiconductor material. The plurality of through holes 23 may be formed by a semiconductor process. Hence, the inner peripheral width D of each of the plurality of through holes 23 can easily be reduced to 0.05 mm or less, and the semiconductor package member 20 having water repellency can be obtained at low cost. Moreover, since more through holes 23 can be formed in a narrower area, the area ratio of the plurality of through holes 23 can be increased. The moisture permeability of the semiconductor package member 20 is improved, and the response speed of the semiconductor device 1 is enhanced.

### <Working Effect>

The semiconductor package member 20 according to an embodiment of the present disclosure includes the substrate 20a. The substrate 20a has the first main surface 21. The recess 46 is formed on the substrate 20a. The substrate 20a includes the plurality of through holes 23. The plurality of through holes 23 are formed to reach the second main surface 22 on the side opposite to the first main surface 21 from the first main surface 21. At least some of the plurality of through holes 23 are formed at a position overlapping the recess 46.

In this manner, since the semiconductor package member 20 has water repellency, liquid such as water is prevented from entering the through holes 23. Thus, when the semiconductor device 1 such as a gas sensor is manufactured by using the semiconductor package member 20, liquid does not accumulate in the through holes 23, and the semiconductor device 1 which maintains excellent moisture permeability can be obtained.

The semiconductor package member 20 includes the water-repellent film 45. The water-repellent film 45 is formed on the first main surface 21 of the substrate 20a. In this way, liquid such as water is further restrained from entering the through holes 23.

In the semiconductor package member 20, the water-repellent film 45 is in contact with at least a portion of the inner peripheral surfaces of the through holes 23 and the recess 46. The water-repellent film 45 may be formed only on a part of the inner peripheral surface of the recess 46 or may be formed in such a manner as to extend from a part of the inner peripheral surface of the recess 46 to the inner peripheral surface of the through hole 23. In this way, if the water-repellent film 45 is formed not only on the first main surface 21 but also on the bottom surface 46a of the recess 46, the first side surface 46b of the recess 46, and the second side surface 23a of the through hole 23, since the area having water repellency increases, liquid such as water is further inhibited from entering the through holes 23.

In the semiconductor package member 20, the contact angle of water with respect to the first main surface 21 and the water-repellent film 45 is 90° or more. By forming the recess 46 and the water-repellent film 45 on the first main surface 21 in this way, the contact angle of water becomes 90° or more. As a result, the semiconductor package member 20 can have high water repellency.

In the semiconductor package member 20, a direction perpendicular to the first main surface 21 is defined as the first direction X. A direction parallel to the first main surface 21 is defined as the second direction Y. The width W of the recess 46 in the second direction Y is 100 μm or less. The depth h of the recess 46 from the first main surface 21 to the bottom surface 46a of the recess 46 in the first direction X is greater than or equal to the width W. In this way, the semiconductor package member 20 can have high water repellency. On the other hand, when the width W exceeds 0.1 mm, water droplets may enter the inside of the recess 46, and the semiconductor package member 20 may lose its water repellency.

In the semiconductor package member 20, the recess 46 includes the first recess 460 and the second recess 461. The direction perpendicular to the first main surface 21 is defined as the first direction X. The direction parallel to the first main surface 21 is defined as the second direction Y. The distance L from the first recess 460 to the second recess 461 in the second direction Y is three times or less the width W of the first recess 460 in the second direction Y. In this way, the fine recesses 46 are arranged on the first main surface 21 in a congested manner, further improving the water repellency of the semiconductor package member 20.

In the semiconductor package member 20, the recess 46 includes the first recess 460 and the second recess 461. In the semiconductor package member 20, the first recess 460 is formed to extend linearly on the first main surface 21. The second recess 461 is formed to extend linearly on the first main surface 21 and intersect with the first recess 460. In this way, the recess 46 is arranged to form a fine pattern, further improving the water repellency of the semiconductor package member 20.

In the semiconductor package member 20, the inner peripheral width D of the through hole 23 is 0.05 mm or less. In this manner, the semiconductor package member 20 can transmit only the gas to be inspected while maintaining water repellency against liquid such as water.

In the semiconductor package member 20, the material of the substrate 20a is silicon. In this manner, the semiconductor package member 20 can be manufactured by a semiconductor process. Accordingly, the semiconductor package member 20 in which the plurality of through holes 23 and the recess 46 are formed can be obtained at low cost, so that the cost of the semiconductor device 1 manufactured with use of the semiconductor package member 20 can be reduced.

The semiconductor package member 20 has a moisture permeability of 100 g/(m²·h) or more. The moisture permeability of the semiconductor package member 20 in which the through holes 23 and the recess 46 are formed can be 100 g/(m²·h) or more. As a result, when the semiconductor device 1 is manufactured with use of the semiconductor package member 20, the semiconductor device 1 with excellent moisture permeability can be obtained.

### Second Embodiment

### <Structure of Semiconductor Device>

FIG. 14 is a schematic cross-sectional view of the semiconductor device 1 of a second embodiment. FIG. 14 corresponds to FIG. 1. The semiconductor device 1 illustrated in FIG. 14 basically has the same configuration as the semiconductor device 1 illustrated in FIGS. 1 to 4, except that the semiconductor package member 20 is connected to the semiconductor element 15. Specifically, the semiconductor package member 20 is connected to the semiconductor element 15 via the bonding member 28. The bonding member 28 is a resin adhesive, for example. The semiconductor element 15 detects the gas 2 that has flowed into the cavity 29 of the semiconductor device 1 through the plurality of through holes 23 of the semiconductor package member 20, and outputs a signal regarding the gas 2, such as the concentration of the gas 2. A signal regarding the gas 2 is output to the outside of the semiconductor device 1 through pads 13 of the semiconductor element 15. The semiconductor package member 20 and the semiconductor element 15 form a chip size package (CSP), for example.

### <Working Effect>

The semiconductor device 1 according to an embodiment of the present disclosure includes the semiconductor element 15 and the semiconductor package member 20. The semiconductor package member 20 is connected to the semiconductor element 15. In this manner, the semiconductor package member 20 and the semiconductor element 15 can form a chip size package.

### Third Embodiment

### <Structure of Semiconductor Device>

FIG. 15 is a schematic cross-sectional view of the semiconductor device 1 of a third embodiment. FIG. 15 corresponds to FIG. 1. The semiconductor device 1 illustrated in FIG. 15 basically has the same configuration as the semiconductor device 1 illustrated in FIGS. 1 to 4, but differs in that the support substrate 10 is a ceramic package. Specifically, a recess is formed in the first surface 10a of the support substrate 10. The semiconductor element 15 is mounted on a bottom surface 11 of the recess.

The support substrate 10 includes the bottom surface 11 that is recessed from the first surface 10a. The bottom surface 11 is the bottom surface of a recess formed on the first surface 10a. The semiconductor element 15 is mounted on the bottom surface 11. As illustrated in FIG. 15, the semiconductor package member 20 basically does not have to have the protrusion 25 of the semiconductor package member 20 illustrated in FIG. 1. Since a recess is formed on the first surface 10a of the support substrate 10, the cavity 29 in which the semiconductor element 15 can be housed is formed between the semiconductor package member 20 and the support substrate 10 even without the protrusion 25.

The support substrate 10 includes pads 14. The pads 14 are provided on the bottom surface 11, for example. The semiconductor element 15 includes pads 16. Conductive wires 19, such as gold (Au) wires, are bonded to the pads 14 and the pads 16. The pads 16 are electrically connected to the pads 14 via the conductive wires 19. Signals regarding the gas 2, such as the concentration of the gas 2, are transmitted and output to the outside of the semiconductor device 1 through the pads 16, the conductive wires 19, the pads 14, and the electrical wiring (not illustrated) and the external terminals (not illustrated) of the support substrate 10. For example, the support substrate 10 is a ceramic package, and the semiconductor package member 20 and the support substrate 10 form a package for the semiconductor element 15.

### <Working Effect>

The semiconductor device 1 according to an embodiment of the present disclosure includes the semiconductor element 15, the ceramic package, and the semiconductor package member 20. The ceramic package holds the semiconductor element 15 inside. The semiconductor package member 20 is connected to a ceramic package. When the support substrate 10 is a ceramic package, the semiconductor package member 20 and the support substrate 10 form a package for the semiconductor element 15.

The embodiments disclosed herein should be considered to be illustrative in all respects and not restrictive. Unless there is a contradiction, at least two of the embodiments disclosed herein may be combined. The basic scope of the present disclosure is indicated by the claims rather than the above description, and it is intended that all changes within the meaning and range which are equivalent to the claims be included.

Modes of the present disclosure are outlined as items below.

### (Item 1)

A semiconductor package member including:
a substrate having a first main surface on which a recess is formed, in which
the substrate includes a plurality of through holes formed in such a manner as to, from a first main surface, reach a second main surface opposite to the first main surface, and
at least some of the plurality of through holes are formed at positions overlapping the recess.

### (Item 2)

The semiconductor package member according to item 1, further including:
a water-repellent film formed on the first main surface of the substrate.

### (Item 3)

The semiconductor package member according to item 2, in which
the water-repellent film is in contact with at least a portion of inner peripheral surfaces of the through holes and the recess.

### (Item 4)

The semiconductor package member according to item 2 or 3, in which
a contact angle of water with respect to the first main surface and the water-repellent film is 90° or more.

### (Item 5)

The semiconductor package member according to any one of items 1 through 4, in which,
when a direction perpendicular to the first main surface is defined as a first direction and a direction parallel to the first main surface is defined as a second direction, a width of the recess in the second direction is 100 μm or less, and
a depth of the recess from the first main surface to a bottom surface of the recess in the first direction is equal to or greater than the width.

### (Item 6)

The semiconductor package member according to according to any one of items 1 through 5, in which
the recess includes a first recess and a second recess, and,
when a direction perpendicular to the first main surface is defined as a first direction, and a direction parallel to the first main surface is defined as a second direction, a distance from the first recess to the second recess in the second direction is equal to or less than three times a width of the first recess in the second direction.

### (Item 7)

The semiconductor package member according to any one of items 1 through 5, in which
the recess includes a first recess and a second recess,
on the first main surface, the first recess is formed to extend linearly, and
on the first main surface, the second recess is formed to extend linearly and intersect with the first recess.

### (Item 8)

The semiconductor package member according to any one of items 1 through 7, in which
an inner peripheral width of each of the through holes is 0.05 mm or less.

### (Item 9)

The semiconductor package member according to any one of items 1 through 8, in which
a material of the substrate is silicon.

### (Item 10)

The semiconductor package member according to any one of items 1 through 9, in which
a moisture permeability is 100 g/(m²·h) or more.

### (Item 11)

A semiconductor device including:
a semiconductor element; and
the semiconductor package member according to any one of items 1 through 10, which is connected to the semiconductor element.

### (Item 12)

A semiconductor device including:
a semiconductor element;
a ceramic package that holds the semiconductor element inside; and
the semiconductor package member according to any one of items 1 through 10, which is connected to the ceramic package.

According to the present disclosure, a semiconductor package member that can prevent water from accumulating in holes can be provided.

What is claimed is:

1. A semiconductor package member comprising:
a substrate having a first main surface on which a recess is formed, wherein
the substrate includes a plurality of through holes formed in such a manner as to, from a first main surface, reach a second main surface opposite to the first main surface, and
at least some of the plurality of through holes are formed at positions overlapping the recess.

2. The semiconductor package member according to claim 1, further comprising:
a water-repellent film formed on the first main surface of the substrate.

3. The semiconductor package member according to claim 2, wherein
the water-repellent film is in contact with at least a portion of inner peripheral surfaces of the through holes and the recess.

4. The semiconductor package member according to claim 2, wherein
a contact angle of water with respect to the first main surface and the water-repellent film is 90° or more.

5. The semiconductor package member according to claim 1, wherein,
when a direction perpendicular to the first main surface is defined as a first direction and a direction parallel to the first main surface is defined as a second direction, a width of the recess in the second direction is 100 μm or less, and
a depth of the recess from the first main surface to a bottom surface of the recess in the first direction is equal to or greater than the width.

6. The semiconductor package member according to claim 1, wherein
the recess includes a first recess and a second recess, and,
when a direction perpendicular to the first main surface is defined as a first direction, and a direction parallel to the first main surface is defined as a second direction, a distance from the first recess to the second recess in the second direction is equal to or less than three times a width of the first recess in the second direction.

7. The semiconductor package member according to claim 1, wherein
the recess includes a first recess and a second recess,
on the first main surface, the first recess is formed to extend linearly, and
on the first main surface, the second recess is formed to extend linearly and intersect with the first recess.

8. The semiconductor package member according to claim 1, wherein
an inner peripheral width of each of the through holes is 0.05 mm or less.

9. The semiconductor package member according to claim 1, wherein a material of the substrate is silicon.

10. The semiconductor package member according to claim 1, wherein
a moisture permeability is 100 g/(m²·h) or more.

11. A semiconductor device comprising:
a semiconductor element; and
the semiconductor package member according to claim 1, which is connected to the semiconductor element.

12. A semiconductor device comprising:
a semiconductor element;
a ceramic package that holds the semiconductor element inside; and
the semiconductor package member according to claim 1, which is connected to the ceramic package.
